(19) United States
(12) Patent Application Publication
(10) Pub. No.: US 2013/0341785 A1
(43) Pub. Date: Dec. 26, 2013

(54) SEMICONDUCTOR CHIP WITH EXPANSIVE UNDERBUMP METALLIZATION STRUCTURES

(71) Applicants: Lei Fu, Austin, TX (US); Xuefeng Zhang, Austin, TX (US); Lihong Cao, Austin, TX (US)

(72) Inventors: Lei Fu, Austin, TX (US); Xuefeng Zhang, Austin, TX (US); Lihong Cao, Austin, TX (US)

(21) Appl. No.: 13/530,835

(22) Filed: Jun. 22, 2012

(51) Int. Cl. H01L 23/498; H01L 21/50; H01L 21/28

(52) U.S. Cl. 257/737; 438/613; 438/106; 438/107; 257/E21.158; 257/E21.499; 257/E23.068

(57) ABSTRACT

Methods and apparatus to protect fragile dielectric layers in a semiconductor chip are disclosed. In one aspect, a method of manufacturing is provided that includes forming a first polymer layer over a conductor pad of a semiconductor chip where the conductor pad has a first lateral dimension. An underbump metallization structure is formed on the first polymer layer and in ohmic contact with the conductor pad. The underbump metallization structure has a second lateral dimension greater than the first lateral dimension. A second polymer layer is formed on the first polymer layer with a first opening exposing at least a portion of the underbump metallization structure.

### BACKGROUND OF THE INVENTION

1. Field of the Invention

This invention relates generally to semiconductor processing, and more particularly to methods and apparatus for coupling a conductor structure, such as a solder bump or conductive pillar, to a semiconductor chip input/output site.

2. Description of the Related Art

Flip-chip mounting schemes have been used for several years to mount semiconductor chips to circuit boards, such as semiconductor chip package substrates. In many conventional flip-chip variants, a plurality of solder joints are established between input/output (I/O) sites of a semiconductor chip and corresponding I/O sites of a circuit board. In one conventional process, a solder bump is metallurgically bonded to a given I/O site or pad of the semiconductor chip and a so-called pre-solder is metallurgically bonded to a corresponding I/O site of the circuit board. Thereafter the solder bump and the pre-solder are brought into proximity and subjected to a heating process that reflows one or both of the solder bump and the pre-solder to establish the requisite solder joint.

In one conventional process, the connection of the solder bump to a particular I/O site of a semiconductor chip entails forming an opening in a top-level dielectric film of a semiconductor chip proximate the I/O site and thereafter depositing metal to establish an under bump metallization (UBM) structure. Solder is next placed by plating or printing. The solder bump is then formed on the UBM structure by reflow. The opening in the dielectric film is shaped with relatively planar sidewalls, that is, without any protrusions or projections. One conventional example uses an octagonal opening. The later-formed UBM structure has an interior wall that matches the planar sidewall configuration of the dielectric opening.

Flip-chip solder joints may be subjected to mechanical stresses from a variety of sources, such as coefficient of thermal expansion mismatches, ductility differences and circuit board warping. These stresses can, in-turn, be imposed on underlying layers, such as interlevel dielectric layers that make up large portions of the metallization system for the semiconductor chip. The interlevel dielectric layers may be relatively brittle and thus prone to fracture from stresses transmitted by the UBM structures.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes forming a first polymer layer over a conductor pad of a semiconductor chip where the conductor pad has a first lateral dimension. An underbump metallization structure is formed on the first polymer layer and in ohmic contact with the conductor pad. The underbump metallization structure has a second lateral dimension greater than the first lateral dimension. A second polymer layer is formed on the first polymer layer with a first opening exposing at least a portion of the underbump metallization structure.

In accordance with another aspect of an embodiment of the present invention, a method of manufacturing is provided that includes mounting a semiconductor chip on a circuit board. The semiconductor chip has plural interconnect structures. Each of the interconnect structures includes a first polymer layer over a conductor pad, where the conductor pad has a first lateral dimension, an underbump metallization structure on the first polymer layer and in ohmic contact with the conductor pad, where the underbump metallization structure has a second lateral dimension greater than the first lateral dimension, a second polymer layer on the first polymer layer and with a first opening exposing at least a portion of the underbump metallization structure and a conductor structure on the portion of the underbump metallization structure. Electrical connections are established between the interconnect structures and conductor structures of the circuit board.

In accordance with another aspect of an embodiment of the present invention, an apparatus is provided that includes a semiconductor chip with a conductor pad that has a first lateral dimension. A first polymer layer is over the conductor pad. An underbump metallization structure is on the first polymer layer and in ohmic contact with the conductor pad. The underbump metallization structure has a second lateral dimension greater than the first lateral dimension. A second polymer layer is on the first polymer layer and has a first opening exposing at least a portion of the underbump metallization structure.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device that includes a semiconductor chip mounted on a circuit board;

FIG. 2 is a sectional view of FIG. 1 taken at section 2-2;

FIG. 3 is a sectional view like FIG. 2, but of an alternate exemplary embodiment of a semiconductor chip with alternative interconnect structure conductor structures;

FIG. 4 is a sectional view of a small portion of a semiconductor chip depicting exemplary passivation structure processing;

FIG. 5 is a sectional view like FIG. 4, but depicting exemplary polymer layer processing;

FIG. 6 is a sectional view like FIG. 5, but depicting exemplary UBM structure processing;

FIG. 7 is a sectional view like FIG. 6, but depicting additional exemplary polymer layer processing;

FIG. 8 is a sectional view like FIG. 7, but depicting various exemplary conductor structure-to-underbump metallization layer processing;

FIG. 9 is a sectional view like FIG. 7, but depicting exemplary solder-bump conductor structure post-reflow;

FIG. 10 is a plan view of an exemplary UBM structure;

FIG. 11 is a plan view like FIG. 10, but depicting an alternate exemplary UBM structure;

FIG. 12 is a plot of simulated dielectric layer stress versus BLM/Bump Ratio; and

FIG. 13 is a pictorial view of an exemplary electronic device with an exemplary semiconductor chip device exploded therefrom.

### DETAILED DESCRIPTION OF SPECIFIC EMBODIMENTS

Various embodiments of a semiconductor chip are described herein. One example includes multiple interconnect structures. Each interconnect structure has an underbump metallization structure positioned on an underlying conductor pad. The underbump metallization structure has a wider lateral dimension than the conductor pad. Polymer layers are positioned above and below the underbump metallization structure. This arrangement lessens stresses imposed on underlying brittle materials, such as low K or ultra low K interlevel dielectric materials. Solder bumps, conductive pillars or others may be formed on the underbump metallization structure. Additional details will now be described.

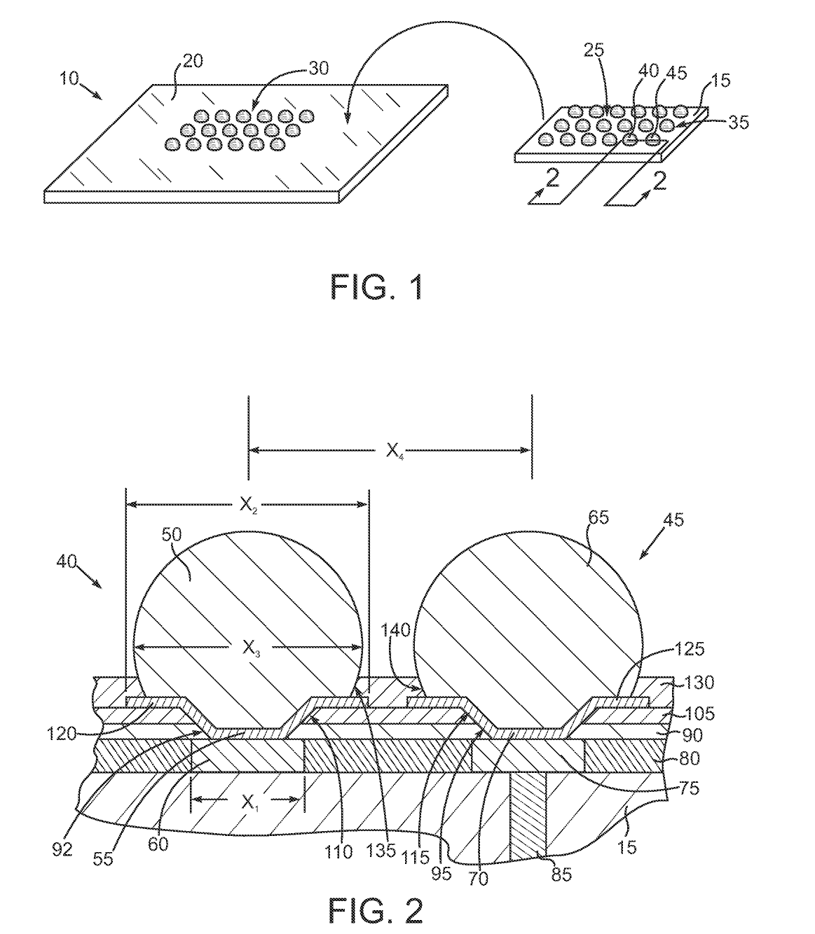

In the drawings described below, reference numerals are generally repeated where identical elements appear in more than one figure. Turning now to the drawings, and in particular to FIG. 1, therein is shown a pictorial view of an exemplary embodiment of a semiconductor chip device 10 that includes a semiconductor chip 15 that may be mounted on a circuit board 20. In this illustrative embodiment, and to illustrate certain features of the semiconductor chip 15, the chip 15 is shown detached and flipped over from its mounting position on the circuit board 20. The semiconductor chip 15 includes multiple interconnect structures 25, which are designed to metallurgically bond with the corresponding array of interconnect structures 30 on the circuit board 20 and form plural joints or other type of solder connections when the semiconductor chip 15 is mounted to the circuit board 20. Note that three of the interconnect structures 25 are separately labeled 35, 40 and 45. The interconnect structures 40 and 45 will be used to illustrate additional features of the semiconductor chip 15 in conjunction with the next figure.

None of the embodiments disclosed herein is reliant on particular functionalities of the semiconductor chip 15 or the circuit board 20. Thus, the semiconductor chip 15 may be any of a variety of different types of circuit devices used in electronics, such as, for example, interposers, microprocessors, graphics processors, combined microprocessor/graphics processors, application specific integrated circuits, memory devices or the like, and may be single or multi-core. The semiconductor chip 15 may be constructed of bulk semiconductor, such as silicon or germanium, or semiconductor-on-insulator materials, such as silicon-on-insulator materials or even insulator materials. Thus, the term “semiconductor chip” even contemplates insulating materials. Stacked dice may be used if desired.

The circuit board 20 may be another semiconductor chip of the type described above, a semiconductor chip package substrate, a circuit card, or virtually any other type of printed circuit board. Monolithic or laminate structures could be used. A build up design is one example of a laminate. In this regard, the circuit board 20 may consist of a central core upon which one or more build-up layers are formed and below which an additional one or more build-up layers are formed. The core itself may consist of a stack of one or more layers. So-called “coreless” designs may be used as well. The layers of the circuit board 20 may consist of an insulating material, such as various well-known epoxies or other resins interspersed with metal interconnects. A multi-layer configuration other than buildup could be used. Optionally, the circuit board 20 may be composed of well-known ceramics or other materials suitable for package substrates or other printed circuit boards.

Additional details of the interconnect structures 40 and 45 may be understood by referring now to FIG. 2, which is a sectional view of FIG. 1 taken at section 2-2. Before turning to FIG. 2 in earnest, it should be noted that section 2-2 passes through a portion of the semiconductor chip 15 that includes the interconnect structures 40 and 45. The following discussion of the interconnect structures 40 and 45 will be illustrative of the other interconnect structures 40 and 45 and related structures. For simplicity of illustration, the full depth of the semiconductor chip 15 is not depicted and the features thereof are not drawn to scale in FIG. 2. The interconnect structure 40 may consist of a conductor structure 50 metallurgically connected to an underlying under bump metallization structure 55. The conductor structure 50 may be a solder bump, conductive pillar or other type of structure. The UBM structure 55 is in turn electrically connected and in ohmic contact with an underlying conductor pad 60. The interconnect structure 45 similarly may consist of a conductor structure 65 like the conductor structure 50 and metallurgically bonded to an underlying UBM structure 70 that is in turn formed in ohmic contact with an underlying conductor pad 75. Various insulating material layers are disposed above and below the UBM structures 55 and 60 and will be described momentarily.

The portion of the semiconductor chip 15 that is visible in FIG. 2 may actually consist of various types of dielectric materials, such as those that may be used in multiple metallization stack schemes. Here, a single dielectric layer 80 is shown, but there may be many. The dielectric layer 80 may be composed of a variety of interlevel dielectric materials, such as tetra-ethyl-ortho-silicate, various other glasses, or so-called “low-K” materials with a K value less than about 3.0 or “ultra low-K” materials with a K value less than about 2.7 that both favor reduced parasitics between displaced conductor layers. Exemplary materials include, for example, porous carbon doped oxides (p-SiCOH), nano porous organosilicate and black diamond film. The skilled artisan will appreciate that the conductor pads 60 and 75 may be part of a topmost layer of interconnect metallization and may be connected to various other electrical structures both laterally and vertically. For example, an interconnect layer 85 is connected to the pad 75. In addition, the skilled artisan will appreciate that somewhere within the confines of the semiconductor chip 15 an active device region with multitudes of integrated circuit elements such as transistors, resistors and others is positioned. The conductor pads 60 and 75 may be composed of a variety of conductor materials, such as copper, aluminum, silver, gold, titanium, refractory metals, refractory metal compounds, alloys of these or the like. In lieu of a unitary structure, the conductor pads 60 and 75 may consist of a laminate of plural metal layers. However, the skilled artisan will appreciate that a great variety of conducting materials may be used for the conductor pads 60 and 75. Various well-known techniques for applying metallic materials may be used, such as physical vapor deposition, chemical vapor deposition, plating or the like. It should be understood that additional conductor structures could be used.

The dielectric layer 80 and the conductor pads 60 and 75 are top coated with a passivation structure 90, which includes openings at 92 and 95 to the underlying conductor pads 60 and 75. The passivation structure 90 is designed to protect the conductor pads 60 and 75 from physical damage and contamination prior to the manufacture of the UBM structures 55 and 70 and attachment of the conductor structures 50 and 65. Exemplary materials include silicon dioxide, silicon nitride, polyimide, laminates of these or the like.

A polymer layer 105 is formed on the passivation structure 90 and includes openings at 110 and 115 to the passivation structure 90. The UBM structures 55 and 70 are formed with respective flange portions 120 and 125 seated on the polymer layer 105. An additional polymer layer 130 may be formed over the polymer layer 105 and parts of the flange portions 120 and 125. The polymer layer 130 is patterned with openings at 135 and 140 leading to the UBM structures 55 and 70 and to accommodate the solder structures 50 and 65. The polymer layers 105 and 130 are designed to provide a compliant protective layer and thus may be composed of a variety of materials, such as polyimide, benzocyclobutene or other insulating materials such as silicon nitride or the like and may be deposited by spin coating, CVD or other techniques. If desired, the polymer layers 105 and 130 may be composed of polyimide infused with photoactive compounds to enable the photolithographic patterning of openings as described below.

The UBM structures 55 and 70 are designed to satisfy a few important objectives, namely, to bond to the overlying solder bump 35 or other solder structure, to establish a conductive interface with an underlying conductor structure, in this case the conductor pads 60 and 75, and to bond as necessary with underlying or surrounding dielectrics, such as the passivation structure 90, all while providing a barrier to the diffusion of solder constituents into underlying conductor structures, which might otherwise degrade those conductor structures. In this illustrative embodiment, the UBM structures 55 and 70 may consist of a laminate of plural metallic layers. The number and composition of such layers may be tailored to a particular bumping process, such as printing or plating for example. For example, the UBM structures 55 and 70 might be constructed for printed solder bump conductor structures 50 and 65 as series of layers applied to the semiconductor chip 15 in succession, such as an adhesion layer of sputtered titanium or titanium-tungsten, followed by a sputtered nickel-vanadium layer, and capped with a sputtered solder-wettable layer of copper or gold. However, in the event that a bump plating process is used to establish the later-formed conductor structures 50 and 65, then the UBM structures 55 and 70 may consist of an adhesion layer of the type described above, followed by a plating seed layer, such as copper deposited by electroless plating or sputter deposition, followed by a nickel or nickel-vanadium barrier layer of the type described above and capped with a plating bar of copper or the like.

If solder is used, the conductor structures 50 and 65 may be composed of a variety of lead-based or lead-free solders. An exemplary lead-based solder may have a composition at or near eutectic proportions, such as about 63% Sn and 37% Pb. High lead examples include (about 97% Pb 3% Sn) and (about 95% Pb 5% Sn). Lead-free examples include tin-silver (about 97.3% Sn 2.7% Ag), tin-copper (about 99% Sn 1% Cu), tin-silver-copper (about 96.5% Sn 3% Ag 0.5% Cu) or the like. These compositions may be varied. Referring again briefly to FIG. 1, the solder structures 30 of the circuit board 20 may be composed of the same types of materials. Optionally, the solder structures 30 may be eliminated in favor of a single solder structure or a solder plus a conducting post arrangement.

The conductor pads 60 and 75 will be fabricated with some lateral dimension X₁, which may be on the order of about 10 to 60 microns. Unlike a conventional UBM structure and conductor pad arrangement described in the Background section above, the UBM structures 55 and 70 in this illustrative embodiment are advantageously fabricated with a wider lateral dimension X₂ than the lateral dimensions X₁ of the underlying conductor pads 60 and 75. The openings at 135 and 140 in the polymer layer 130 are advantageously patterned and the exemplary process to form the conductor structures 50 and 65 to be described below is tailored so that the post reflow lateral dimension X₃ of the conductor structures 50 and 65 is slightly smaller than the lateral dimension X₂ of the UBM structures 55 and 70. Even with this enlargement of the UBM structures 55 and 70, namely, the lateral dimension X₂, a satisfactory conductor structure pitch X₄ may be realized. For example, a conventional conductor structure pitch may be about 180 microns and the lateral dimension of the conductor structures for a conventional design may be about 120 microns and the lateral dimension of the UBM structure will be about 120 microns. However in this illustrative embodiment, the value for the lateral dimension X₂ of the UBM structures 55 and 70 may be about 100 to 120 microns, the lateral dimension of the conductor structures 50 and 65 may be about 90 microns and the pitch X₄ may be about 150 microns, which is an improvement of about 30 microns over a conventional design. These exemplary dimensions may scale downward with improvements in fabrication processes.

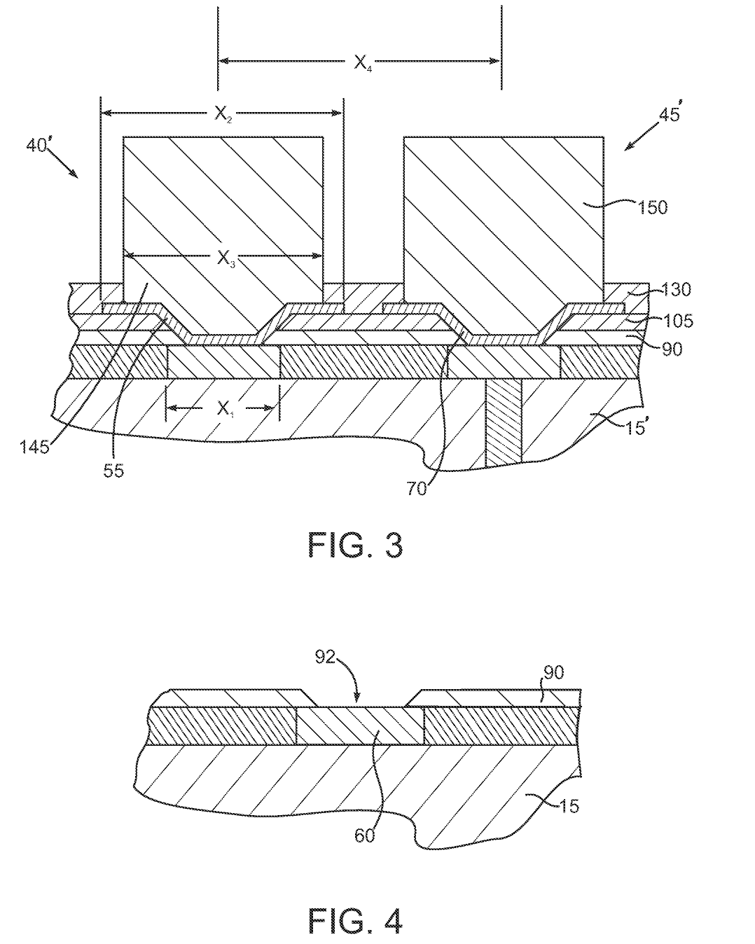

An alternate exemplary embodiment of the semiconductor chip 15′ may be understood by referring now to FIG. 3, which is a sectional view like FIG. 2. In this illustrative embodiment, interconnect structures 40′ and 45′ substitute for the interconnect structures 40 and 45 described above in conjunction with FIGS. 1 and 2. In lieu of solder bumps, the interconnect structures 40′ and 45′ include respective conductor structures 145 and 150 fabricated as conductive pillars and metallurgically bonded to the underlying UBM structures 55 and 70. In other respects, the circuit board 15′ may be substantially identical to the circuit board 15 described above in conjunction with FIGS. 1 and 2. Thus, a passivation structure 90 may be topped with two polymer layers 105 and 130. The conductive pillars may be fabricated from a variety of conducting materials, such as, for example, copper, silver, platinum, gold, palladium, combinations or laminates of these or other conductor materials as desired. The well known material deposition processes may be used such as plating, chemical vapor deposition, physical vapor deposition or others. The conductive pillars 145 and 150 may be constructed so that the same relationships as to the relative lateral dimensions X₁, X₂, X₃ and X₄ described above are maintained. Thus, the conductive pillars may be fabricated with some lateral dimension X₃ that is somewhat smaller than the lateral dimension X₂ of the UBM structures 55 and 70 and so that there is a pitch X₄ between the conductive pillars 145 and 150. The value of X₄ for the embodiment in FIG. 3 need not match the value of X₄ for a solder type interconnect structure such as the one depicted in FIGS. 1 and 2.

An exemplary method for fabricating the interconnect structure 40 and the related intermediary films and layers depicted in FIGS. 1 and 2 may be understood by referring now to FIGS. 4, 5, 6, 7, 8 and 9 and initially to FIG. 4. The following exemplary process will be illustrative of the other interconnect structures 25 depicted in FIG. 1 for example. Referring initially to FIG. 4, the conductor pad 60 may be formed on the semiconductor chip 15 from a variety of conductor materials, such as aluminum, copper, silver, gold, titanium, refractory metals, refractory metal compounds, alloys of these or the like. In lieu of a unitary structure, the conductor pad 60 may consist of a laminate of plural metal layers. However, the skilled artisan will appreciate that a great variety of conducting materials may be used for the conductor pad 60. Various well-known techniques for applying metallic materials may be used, such as physical vapor deposition, chemical vapor deposition, plating or the like.

The passivation structure 90 may be next applied to the semiconductor chip 15 as a blanket layer or laminate of layers. Following application, the opening at 92 may be formed in the passivation structure 90. The opening at 92 may be formed in a variety of ways, such as wet or dry etching, laser drilling or others. Suitable masking may be used.

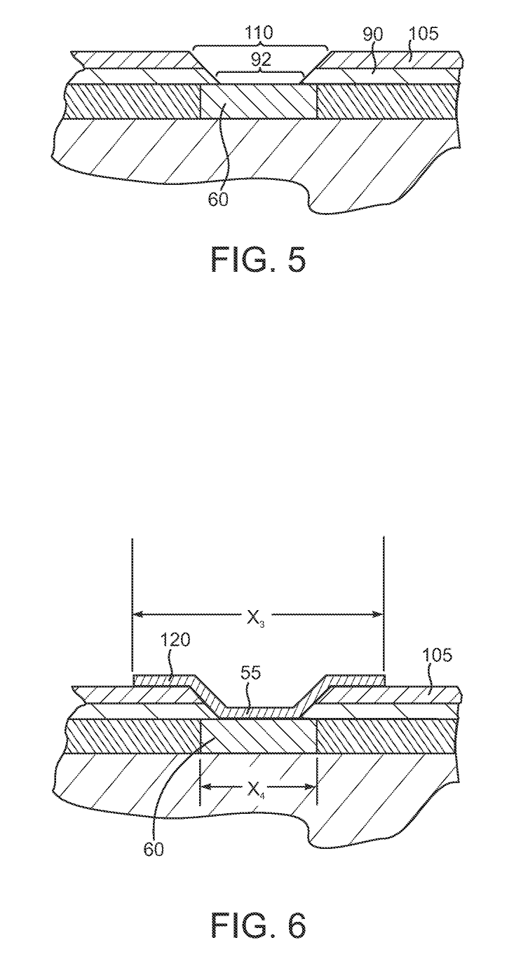

As shown in FIG. 5, the polymer layer 105 may be applied to the passivation structure 90 and patterned with the opening at 110 that again exposes the conductor pad 60. Spin coating or other application techniques may be used to apply the polymer layer 105. In order to create the opening at 110, the polymer layer 105 may be lithographically patterned. This may be done in a variety of ways depending on the composition of the polymer layer 105. A polyimide polymer layer 105 may be infused with a photoactive compound(s) lithographically patterned. In this illustrative embodiment, the polymer layer 105 does contain photoactive compounds. A suitable non-contact mask (not shown) may be applied to the polymer layer 105 and the polymer layer 105 subjected to exposure and developing to produce the opening at 110. A bake cure is next performed on the polymer layer 105. Of course, chemical etching, laser drilling or other patterning techniques could be used. The opening at 110 is preferably at least coextensive with the opening at 92.

Next, and as shown in FIG. 6, the UBM structure 55 may be fabricated with the flange portion 120 on the polymer layer 105 and the lateral dimension X₃ using the techniques described above. The UBM structure 55 may be initially formed as a blanket that is subsequently patterned. A suitable etch mask (not shown) may be applied, particularly at the location slated for eventual solder bump attachment and thus in alignment with the conductor pad 60, and an etch process performed to reduce the size of the UBM structure 55. Following the etch, the UBM structure 55 is patterned like an island but with the flange portion 120. The etch chemistry and process suitable for etching the UBM structure 55 will depend upon the composition of the constituent layers. For example, a copper solder-wettable layer and nickel or nickel-vanadium layer may be etched using a hot phosphoric acid etch and a titanium adhesion layer may be etched using an HF etch. Although technically more complex, an island-like UBM structure 55 layer could be alternatively constructed by selective material addition, such as by lift-off processing. Following the etch, the mask (not shown) may be removed by ashing, solvent stripping or the like. The mask (not shown) may be formed from positive tone resist, a hard mask or a non-contact mask. Patterning may be by well-known photolithography.

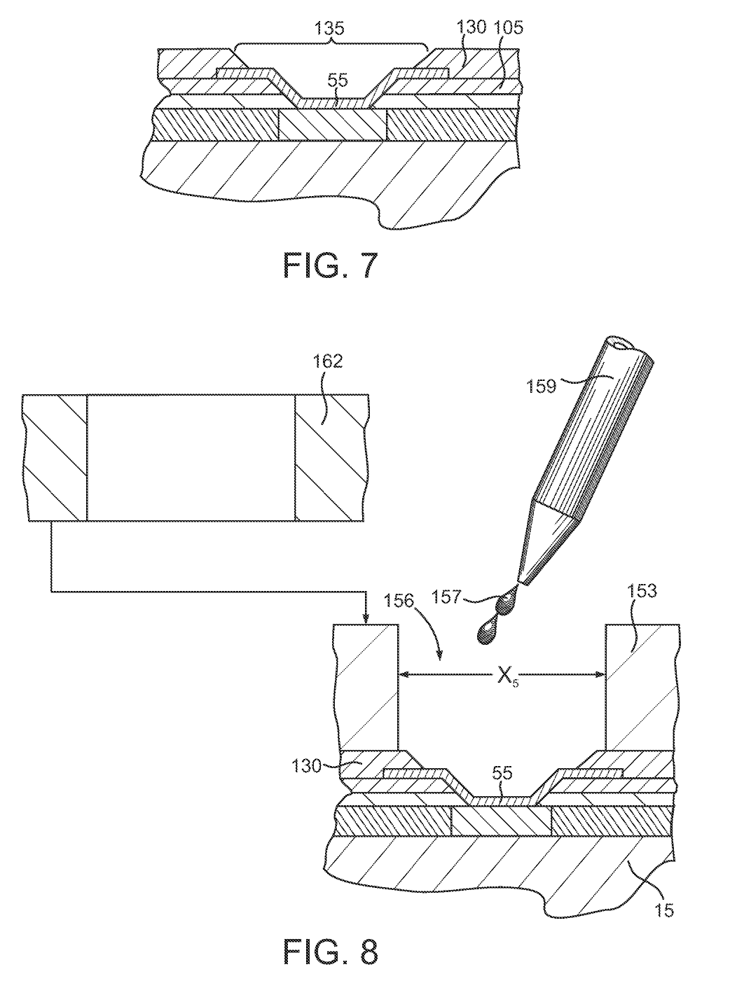

Next and as shown in FIG. 7, the second polymer layer 130 may be formed on the UBM structure 55 and the polymer layer 105 and patterned with the opening at 135 that exposes a significant portion of the UBM structure 55. Spin coating or other application techniques may be used to apply the polymer layer 130. In order to create the opening at 135, the polymer layer 130 may be lithographically patterned. This may be done in a variety of ways depending on the composition of the polymer layer 130. A polyimide polymer layer 130 may be infused with a photoactive compound(s) lithographically patterned. In this illustrative embodiment, the polymer layer 130 does contain photoactive compounds. A suitable non-contact mask (not shown) may be applied to the polymer layer 130 and the polymer layer 130 subjected to exposure and developing to produce the opening at 135. A bake cure is next performed on the polymer layer 130. Of course, chemical etching, laser drilling or other patterning techniques could be used.

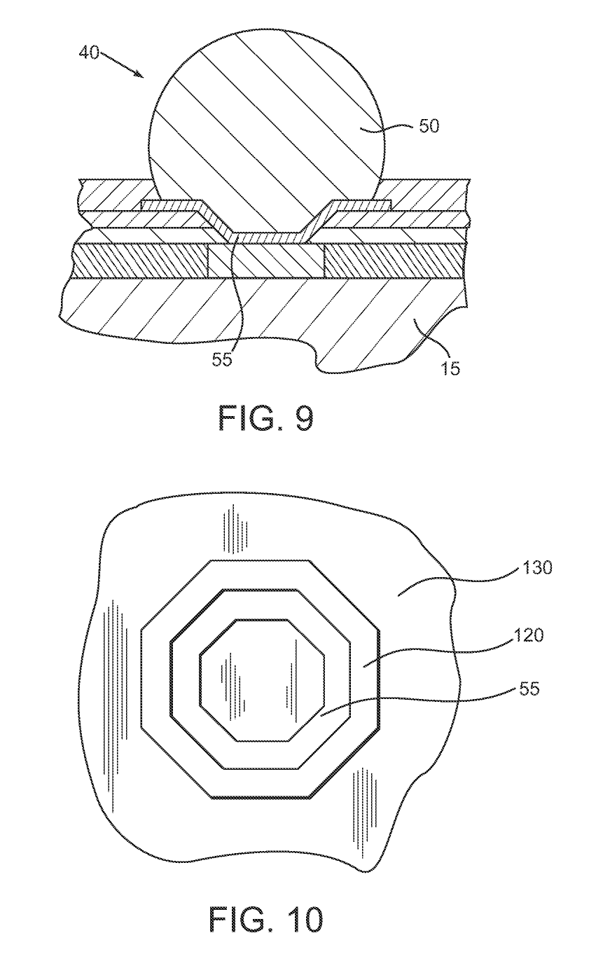

Next and as shown in FIG. 8, a suitable lithography mask 153 may be formed on the UBM structure 55 and the polymer layer 130 and patterned with an appropriate opening 156 of sufficient lateral dimension X₅ such that at least a significant percentage of the UBM structure 55 is exposed. Thereafter, a conductor material 157 is delivered into the opening 156. The conductor material 157 may be a solder or conductive pillar material described elsewhere herein. A suitable applicator 159 or other device may used to delivered the conductor material 157. For example, solder as the conductor material 157 may be applied with the mask 153 in place either by printing or plating as desired. If a printing process is used, then an appropriate stencil 162 may be used to initially apply the conductor material 157. Thereafter, a suitable reflow process may be used to temporarily liquify the conductor material 157 and yield the interconnect structure 40 with the solder structure 50 bonded to the UBM structure 55 as shown in FIG. 9. If a plating process is used, then the need for a stencil 162 is eliminated and the conductor material 157 may be plated using the mask 153. The same is true if a plated conductor pillar, such as the pillar 145 depicted in FIG. 3, is fabricated. The semiconductor chip 15 may be coupled to the circuit board 20 and a reflow performed to merge the interconnect structures 25 and 30 shown in FIG. 1.

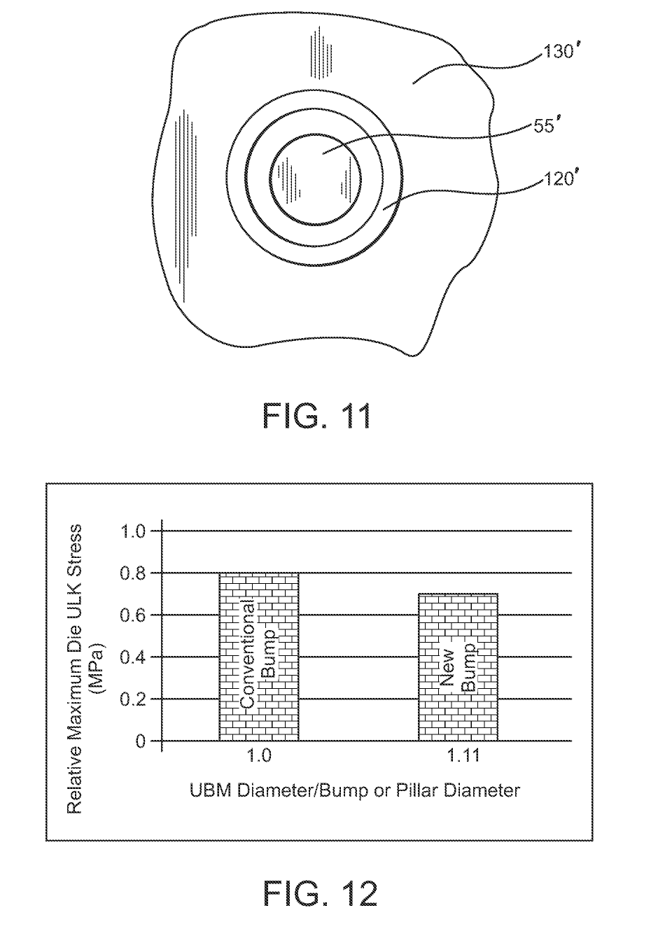

FIGS. 10 and 11 depict successive plan views of embodiments of the UBM but without a solder structure or conductor pillar in place. FIG. 10 depicts the UBM structure 55 with a generally octagonal footprint. Note that the flange portion 120 of the UBM structure 55 and the polymer layer 130 are visible. FIG. 12 depicts a plan view of an alternate UBM structure 55′ that has a generally circular footprint. Again, the polymer layer flange portion 120′ of the UBM structure 55′ and the polymer layer 130 are visible. Of course, the UBM structures 55 and 55′ may take on a variety of different types of footprints.

FIG. 12 is a plot of Relative Maximum Die Stress versus UBM Diameter/Bump (or pillar) Diameter for an ultra low K interlevel dielectric material layer, such as the layer 80 depicted in FIG. 2. The plot shows a simulation of ultra low K interlevel dielectric layer stress for a conventional interconnect and bump and a new interconnect and bump. The conventionally-configured UBM structure that has the same lateral dimension as the underlying conductor pad (thus the UBM Diameter/Bump Diameter ratio has a value of 1) and the new bump design utilizing the enlarged lateral dimension UBM structure, such as the UBM structure 55 depicted and described elsewhere herein, with a UBM Diameter/Bump Diameter ratio of 1.11. Note that the ULK interlevel dielectric stress level for the new bump is approximately 0.7 MPa versus 0.8 MPa for the conventional bump and UBM design. This represents over a 10% reduction in stress in the ULK interlevel dielectric material.

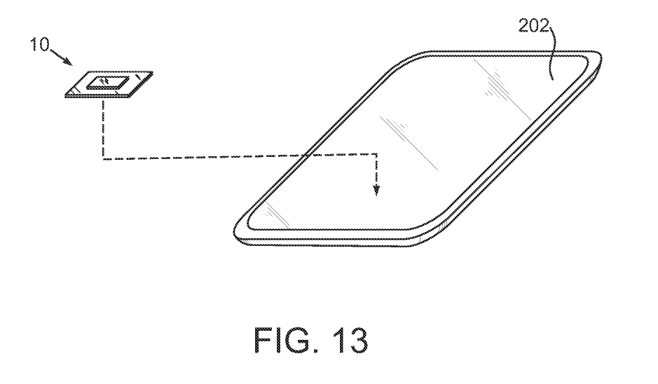

Any of the disclosed embodiments of the semiconductor chip devices may be mounted in another electronic device 202 as shown in FIG. 13. Here, the semiconductor chip device 10 is shown exploded from the electronic device 202. The electronic device 202 may be a computer, a digital television, a handheld mobile device, a personal computer, a server, a memory device, an add-in board such as a graphics card, or any other computing device employing semiconductors.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
forming a first polymer layer over a conductor pad of a semiconductor chip, the conductor pad having a first lateral dimension;
forming an underbump metallization structure on the first polymer layer and in ohmic contact with the conductor pad, the underbump metallization structure having a second lateral dimension greater than the first lateral dimension; and
forming a second polymer layer on the first polymer layer and with a first opening exposing at least a portion of the underbump metallization structure.

2. The method of claim 1, comprising forming a solder bump on the portion of the underbump metallization structure.

3. The method of claim 1, comprising forming a conductive pillar on the portion of the underbump metallization structure.

4. The method of claim 1, wherein the first and second polymer layers comprise polyimide.

5. The method of claim 1, wherein second polymer layer includes a photoactive compound enabling lithographic formation of the first opening.

6. The method of claim 5, wherein the first polymer includes a photoactive compound enabling lithographic formation of a opening exposing a portion of the conductor pad.

7. The method of claim 1, comprising mounting the semiconductor chip on a circuit board.

8. The method of claim 7, comprising mounting the circuit board in an electronic device.

9. A method of manufacturing, comprising:
mounting a semiconductor chip on a circuit board, the semiconductor chip having plural interconnect structures, each of the interconnect structures including a first polymer layer over a conductor pad, the conductor pad having a first lateral dimension, an underbump metallization structure on the first polymer layer and in ohmic contact with the conductor pad, the underbump metallization structure having a second lateral dimension greater than the first lateral dimension, a second polymer layer on the first polymer layer and with a first opening exposing at least a portion of the underbump metallization structure and a conductor structure on the portion of the underbump metallization structure; and
establishing electrical connections between the interconnect structures and conductor structures of the circuit board.

10. The method of claim 9, wherein the conductor structure comprises a solder bump.

11. The method of claim 9, wherein the conductor structure comprises a conductive pillar.

12. The method of claim 9, wherein the first and second polymer layers comprise polyimide.

13. The method of claim 7, comprising mounting the circuit board in an electronic device.

14. An apparatus, comprising:
a semiconductor chip including a conductor pad having a first lateral dimension;
a first polymer layer over the conductor pad;
an underbump metallization structure on the first polymer layer and in ohmic contact with the conductor pad, the underbump metallization structure having a second lateral dimension greater than the first lateral dimension; and
a second polymer layer on the first polymer layer and with a first opening exposing at least a portion of the underbump metallization structure.

15. The apparatus of claim 14, comprising a solder bump or a conductive pillar on the portion of the underbump metallization structure.

16. The apparatus of claim 14, wherein the first and second polymer layers comprise polyimide.

17. The apparatus of claim 14, wherein second polymer layer includes a photoactive compound enabling lithographic formation of the first opening.

18. The apparatus of claim 17, wherein the first polymer includes a photoactive compound enabling lithographic formation of a opening exposing a portion of the conductor pad.

19. The apparatus of claim 14, comprising a circuit board coupled to the semiconductor chip.

20. The apparatus of claim 19, comprising an electronic device, the circuit board being mounted in the electronic device.
